(19) United States
(12) Patent Application Publication
(10) Pub. No.: US 2010/0045265 A1
(43) Pub. Date: Feb. 25, 2010

(54) METHOD AND DEVICE FOR FORMING A TEMPORARY ELECTRICAL CONTACT TO A SOLAR CELL

(75) Inventors: Jorg KIESEWETTER, Thiendorf OT Sacka (DE); Michael TEICH, Moritzburg OT Friedewald (DE); Axel BECKER, Dresden (DE); Claus DIETRICH, Thiendorf OT Sacka (DE); Robert HENTSCH, Dresden (DE); Frank ZILL, Riesa (DE)

Correspondence Address: HESLIN ROTHENBERG FARLEY & MESITI PC, 5 COLUMBIA CIRCLE, ALBANY, NY, 12203, US

(73) Assignee: SUSS MICROTEC TEST SYSTEMS GMBH, Sacka (DE)

(21) Appl. No.: 12/541,530

(22) Filed: Aug. 14, 2009

(30) Foreign Application Priority Data
Aug. 19, 2008 (DE) 102008038184.5-35

(51) Int. Cl. G01R 1/06; H01R 4/58; H01R 33/945; H05K 3/30

(52) U.S. Cl. 324/149; 439/86; 439/577; 29/832

(57) ABSTRACT

In a method and devices for forming a temporary electrical contact to a solar cell for testing purposes, probes form a contact to the electrode terminals of a solar cell held by a sample holder. The probes are held by a probe holder and exhibit an elastic, electrically conductive contact element and at least one reference sensor. In order to form a contact, the solar cell and the probes are positioned in relation to each other, and then a probe is placed on an electrode terminal of the solar cell. To this end, a feed motion of the probe is carried out until a reference sensor of the probe generates a reference signal upon reaching a predefined distance. Then the feed motion is continued by a predefined path that goes beyond the contact element making contact with the electrode terminal, in order to carry out an overtravel.

The invention relates to a method for forming a temporary electrical contact to a solar cell for testing purposes. In this case at least one solar cell, comprising at least two electrode terminals for making the electrical contact, is held by means of one sample holder, and at least one probe is held by means of a probe holder. The probe serves to form a contact to an electrode terminal of the solar cell. In order to form a contact, the solar cell and the probe have to be positioned in relation to each other, and then the probe is placed on the electrode terminal of the solar cell. The invention also relates to probes and devices for carrying out the method.

During the manufacturing process of solar cells and solar modules, consisting of solar cells, it is necessary to form an electrical contact to the front and/or rear sided contacts for the purpose of performance testing. In this case both a reliable electrical contact and also the mechanical sensitivity of the solar cells ought to be taken into consideration. On the one hand, the mechanical sensitivity demands a minimization of the force, with which a mechanical and, thus, an electrical contact is made by means of the probes. On the other hand, a defined force is necessary in order to make a reliable contact and to guarantee such a reliable contact during the measurement procedure. In particular, on forming a simultaneous contact to several electrode terminals of a solar cell, the result is such high forces that can cause damage to the solar cell owing to the mechanical strains or stresses, especially if the solar cell is supported by a holder only at certain points during the testing for minimal shading or for the possibility of forming a bilateral contact.

Thus, for example, US 2007/0068567 A1 discloses the state of the art for forming a temporary electrical contact. In this context it describes a solar cell that is made of crystalline silicon. A contact to the conductor paths of this solar cell—said paths being referred to as “fingers”—is formed directly or via those collecting bars—the so-called bus bars—which form a contact to the conductor paths, by means of several contact heads, each of which has a diameter of a few millimeters and is pressed onto the solar cell by means of springs. In order to prevent the contact heads from causing any damage, the probes, which are designed as flexible, elongated conductors, are pressed onto the one side or both sides of the contacts of the solar cell in the 2007/0068567 A1. In this method of forming a contact to the solar cell, a relatively high and, moreover, also locally extremely differentiated force is exerted on the solar cell, in order to make a reliable electrical contact on all fingers and over the whole bus bar, even in the event that the solar cell is uneven or tilted or in the event that the probes are not parallel. In addition, the handling of thin and brittle solar cells, in order to deliver into a testing station or in US 2007/0068567 A1 for positioning between two opposite probes and for removal after testing, also generates stress loads that can lead to damage to the solar cell. The latter is an especially critical factor for the manufacture of solar cells in a continuous flow facility, because the handling in such a facility is often done by robots and for reasons relating to time and costs the learned sequences of movement—for example, in the case of deviations and the shape and position of the solar cells—can be corrected only under certain condition. Thus, the invention is based on the problem of providing a method and the related useful devices, with which a solar cell can be handled with minimal mechanical stress in a test station and with which the contact tips form a mechanical and electrical contact to the solar cell. Furthermore, the method and the device shall also be suited for integration into industrial continuous flow processes.

The problem is solved by a method, which makes it possible to control the feed motion of one probe or a plurality of probes, so that the force, introduced with the probes, can be precisely metered and adapted to the respective conditions. The control process is achieved by means of a reference sensor of the probe in that known geometric relations between the reference sensor, the one contact element or also a plurality of contact elements of the probe, and the one electrode terminal or a plurality of electrode terminals of the solar cell are used as a basis of the feed motion, starting from a measured location of the probe relative to the solar cell. This location, referred to hereinafter as the reference position, is indicated by a signal of the reference sensor, which is designed and arranged in such a manner that it measures a distance from a reference surface on the solar cell. On reaching the reference position, a defined geometric relation between the contact element and an electrode terminal of the solar cell is produced, and this adjustment of the reference sensor at a pre-defined distance from a reference surface of the solar cell is indicated by an electric signal of the reference sensor—a reference signal. Following the first section of the feed motion up to the reference position is a final feed motion, with which the contact element can touch down on the electrode terminal, and then a subsequent overtravel along a known and, thus, also programmable path can ensue.

In this context the feed motion is defined as the movement of the probe that is performed by the probe after producing a relative position between the probe and the solar cell in one direction up to finally making contact. Therefore, the movement consists of the feed motion as far as up to reaching the position, which is signaled by the reference sensor, the subsequent continuation of this movement in the same direction until a contact element touches an electrode terminal, and in addition, the continuation of this feed motion, which is generally referred to as the overtravel and which is intended for making a reliable contact, which is independent of, for example, mechanical or thermal stresses. The overtravel is a variable that depends chiefly on the materials that are used for the components that are to be brought into contact with each other, on the size of the connection areas, on the technology of the machines performing the movement, and on the tolerances of these parameters. This variable is usually determined by trial and error in order to ensure that during overtravel the probe is not elastically deformed, an area, with which contact is to be made, is not punctured by the probe or damaged in some other place, and the probe does not leave this area—for example, due to a shifting of the components in relation to each other. Once the overtravel is known from a series of tests at the contact-making device that is used, the feed motion can be controlled as far as up to making a reliable contact.

Starting from the reference position, a position between a contact element and an electrode terminal of the solar cell is reached. This position is defined exclusively by the device. On the one hand, the reference sensor is determined geometrically by its mounting on the probe in relation to the tip of the contact element over its arrangement relative to a mounting plane as the reference plane. On the other hand, the position of the reference surface on the solar cell in relation to its electrode terminal is known. The connection between the two geometric systems is produced upon reaching the reference position in connection with the feed motion in only one direction.

To the extent that up to this point and in the following only one contact element—a probe or an electrode terminal—is described, it also relates to a plurality thereof, because in these cases, too, an exact geometric assignment is also possible in the described manner. In this manner it is possible to form a contact to various electrode terminals. Hence, placement on a single small connection is just as possible as forming a simultaneous contact to a complex connection structure or a collecting bar—known as a “bus bar”—of monocrystalline or polycrystalline solar cells. It is even possible with the described method to form a contact to their parallel so-called fingers.

The feed motion of the probe that is to be completed after the reference signal depends on the relative position of the contact elements to the reference sensor. The position of the reference sensor in turn depends, for example, on the type of sensor. When a probe sensor is used, its probe tip will lie in a plane with the tip of the contact element, so that the contact element of the probe is already resting on the electrode terminal, when the reference signal is produced, and the subsequent final feed motion serves only the overtravel. In the case of sensors that measure a distance, such as optical sensors, the final feed motion is put together in the same way as described above.

In one embodiment of the method, the use of suitable contact elements allows a so-called “scrub” action to be carried out during overtravel. In this case the displacement of the contact tips during overtravel allows the contact tips to scrub the electrode terminal and, in so doing, remove any contaminants or passivation layers. In this way it is possible to enhance the contact reliability by merely performing the feed motion. To the extent that in one embodiment the reference sensor also exhibits the reference elements, which are comparable to the contact elements, it is also possible for the reference elements to carry out the scrub action in order to generate a reliable reference signal. Moreover, when an elastically deformable, electrically conductive plastic body is used as the contact element, a scrub action can be carried out owing to a structuring of the surface of the plastic body and a lateral movement of the probe.

The reference surface can be surfaces, which are always present on the solar cell—for example, a electrode terminal, to which the contact is to be formed, or an additional surface, which is also fabricated separately. When the solar cell is brought into direct contact with a mounting surface of the sample holder, the reference surface can also be arranged on the sample holder. In this case the above-described known geometric relations have to be produced by positioning the solar cell exactly in relation to this external reference surface.

As an alternative, a plurality of reference sensors can also be used for controlling the feed motion. For example, in the case of two-dimensionally expanded probes or probe carriers with linearly or planarly distributed probes, the feed motion can be controlled in a locally differentiated manner by means of a suitable number and suitable positions of reference sensors. This is supported if a suitable holder of a probe or probe carrier makes it possible to tilt it about one axis or two axes. To this end, a probe or a probe carrier, which accepts a plurality of probes, which extend along one direction of expansion or extend in one plane, is mounted on the probe holder with two or more joints, so that the system is determined statically. That is, the number of reactions in these positions is equal to the number of degrees of freedom of the probe or probe carrier. This approach prevents stresses that could cause damage to either the probe or the solar cells or to both from occurring in the probe or the solar cells.

This problem is also solved by a probe, which comprises a reference sensor, which is in a defined geometric position relative to a contact element of the probe, with which the electrical contact is made by placing on an electrode terminal. A defined relative position is both the arrangement in the immediate vicinity to each other and a lateral and/or vertical offset to each other. Since the reference sensor is a component of the probe, the reference sensor is moved jointly with the probe, so that the relative position is not changed. A geometric reference of the probe to the device and, in particular, to its positioning and motion system is produced routinely by the mounting of the probe, so that one or more contact elements and of these especially the tips are aligned with respect to a mounting plane. Using a plane as a reference makes it possible to align several contact elements in relation to this plane, so that, for example, the tips of the contact elements lie in a plane that runs parallel to the mounting plane.

In one embodiment a probe exhibits a three fingered structure. In this case the fingers lie so close next to one another that they can be placed side by side even on an electrode terminal surface of less than one millimeter. The middle finger of such a structure constitutes the contact element, whereas the two outer fingers are the reference elements that are driven with a defined reference potential—for example, a ground potential—that does not have a deleterious effect on the measurement for the purpose of generating a reference signal. All three fingers are mounted resiliently and in a boom like manner to a pedestal so that during the brief continuation of the feed motion after having touched down on the electrode terminal—the overtravel—the tips of the fingers experience a deflection that exhibits one directional component in the feed motion and one directional component at a right angle thereto. In this way the feed motion makes possible the above-described “scrub,” because the directional component of the deflection of the tip of the contact element that runs perpendicularly to the feed motion causes the scrubbing action of the tip over the electrode terminal.

Owing to a time delay, which usually occurs while placing the reference element or a probe sensor, between the contact signal and the actual end of the feed motion, there is an adequate overtravel, often just because of this delay, that is induced by the measurement technology.

In a comparable manner a series of contact elements can be arranged next to each other. These contact elements are connected in parallel for the purpose of joint placement on a highly resistive electrode terminal, like a printed bus bar. In order to prevent, in the event of such a linear or planar expansion of a probe, the probe from tilting in relation to the electrode terminal surface and, thus, falsifying the test, the probe can exhibit two or more reference sensors, which signal a uniform distance of different points of the probe from the solar cell. In this case as large a distance as possible between the reference sensors would achieve the best leveling of the probe. In this context the reference sensors can be two fingers, which are driven with a reference potential and which are intended to generate a contact signal, as the reference signal, or additional suitable touch sensors or position sensors.

Moreover, the problem is solved by a device, which exhibits such a probe as well as suitable motion and positioning devices for positioning the solar cell and the probe independently of each other and in relation to each other and the final feed motion of the probe in relation to the solar cell. The positioning of the solar cell and/or the probe can concern, depending on the preceding or subsequent fabrication sequences or test runs, not only one of the two but also just both together. In the latter case the solar cell is moved together with the sample holder; and the probe is moved together with the probe holder. In addition, the positioning can be divided into coarse and fine positioning. As a result of the positioning movement, the solar cell and the probe are in such a relation to each other that the probe can be fed in only one direction to the solar cell in order to make the contact. A suitable control unit can be used to receive the reference signal, which is evaluated and then provided for the purpose of controlling the final feed motion and, thus, the overtravel.

According to one embodiment of the device, a suitable sample holder allows the solar cell to be accepted at the input and the output of a test station as well as allows almost total surface contact of the solar cells when forming a contact and during a measurement operation in that the mounting surface of the sample holder is adapted to the irregularities in the position and structure of the solar cell. Hence, even in the event of forming a simultaneous contact with several probes, any excessive mechanical stress on the solar cell is absorbed because of its resting with all of its surface on the sample holder.

In addition, the sample holder can be designed in such a manner that it is also possible to form a bilateral contact to the solar cell. For this purpose the sample holder exhibits recesses, the size and shape of which matches the arrangement of the electrode terminals on the side of the solar cell, with which it rests on the sample holder. It shall be called in this case the rear side without any additional reference to the configuration of the solar cell.

Combined with the sample holder is a probe holder, which holds one probe or in one embodiment also a plurality of probes in a defined position to each other. This position corresponds to the position of the electrical contacts of the solar cell, to which a contact is to be formed simultaneously. The probe holder is positioned relative to the solar cell in such a manner that a final feed motion of the probes in only one direction can produce the mechanical and electrical contact.

The invention shall be explained in detail below by means of one embodiment. It is apparent from the related drawing that

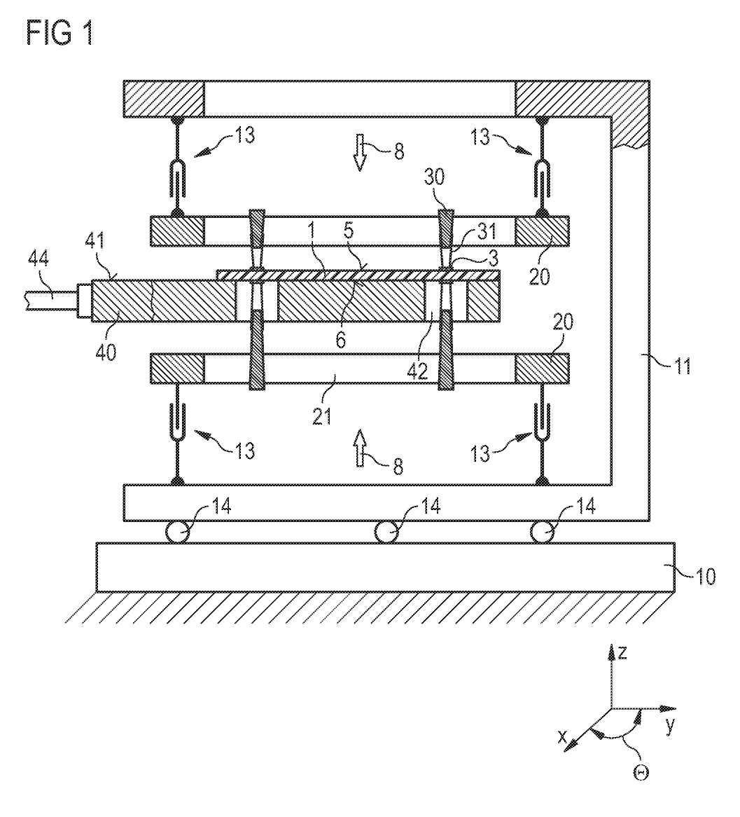

FIG. 1 is a vertical sectional view of a test rig for electrical performance testing of solar cells.

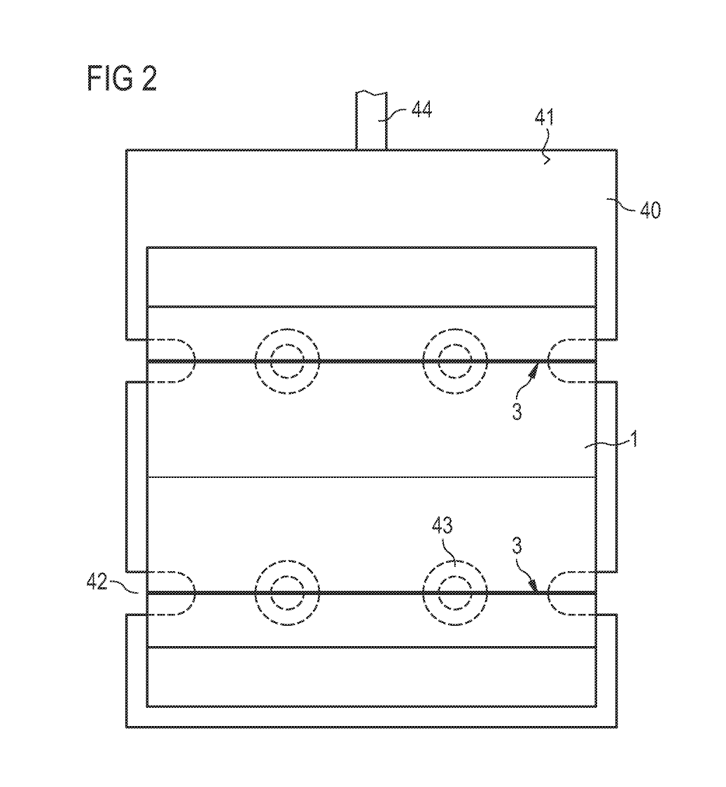

FIG. 2 is a top view of a sample holder for holding solar cells.

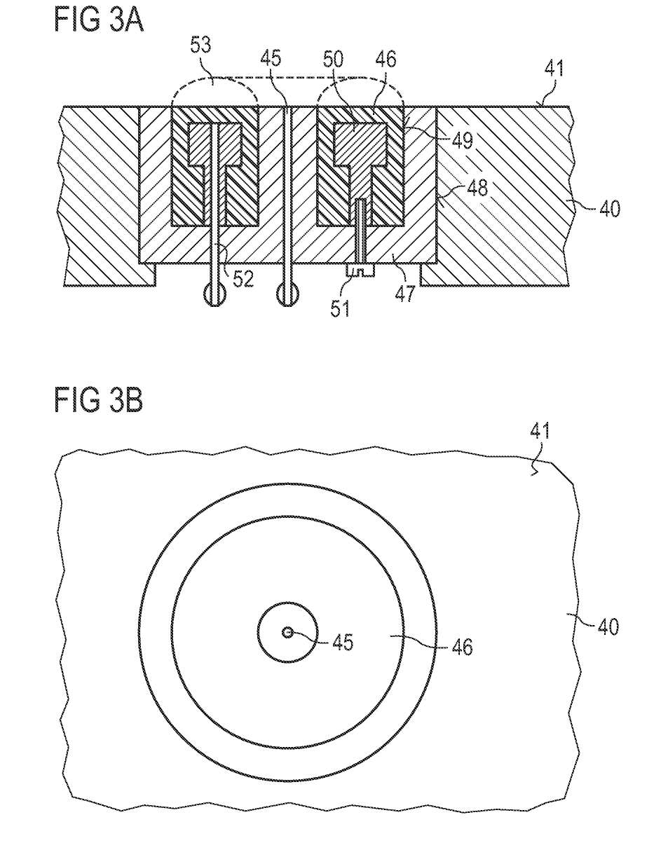

FIGS. 3A, 3B show details of a resilient vacuum suction mechanism of the sample holder, according to FIG. 2, in a sectional view and top view.

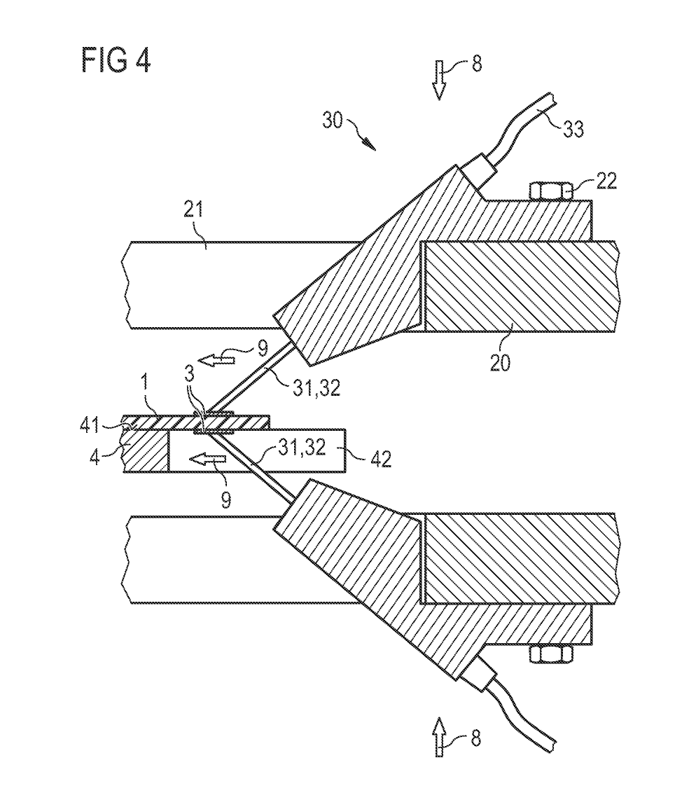

FIG. 4 depicts two probes forming a bilateral contact to a solar cell; and

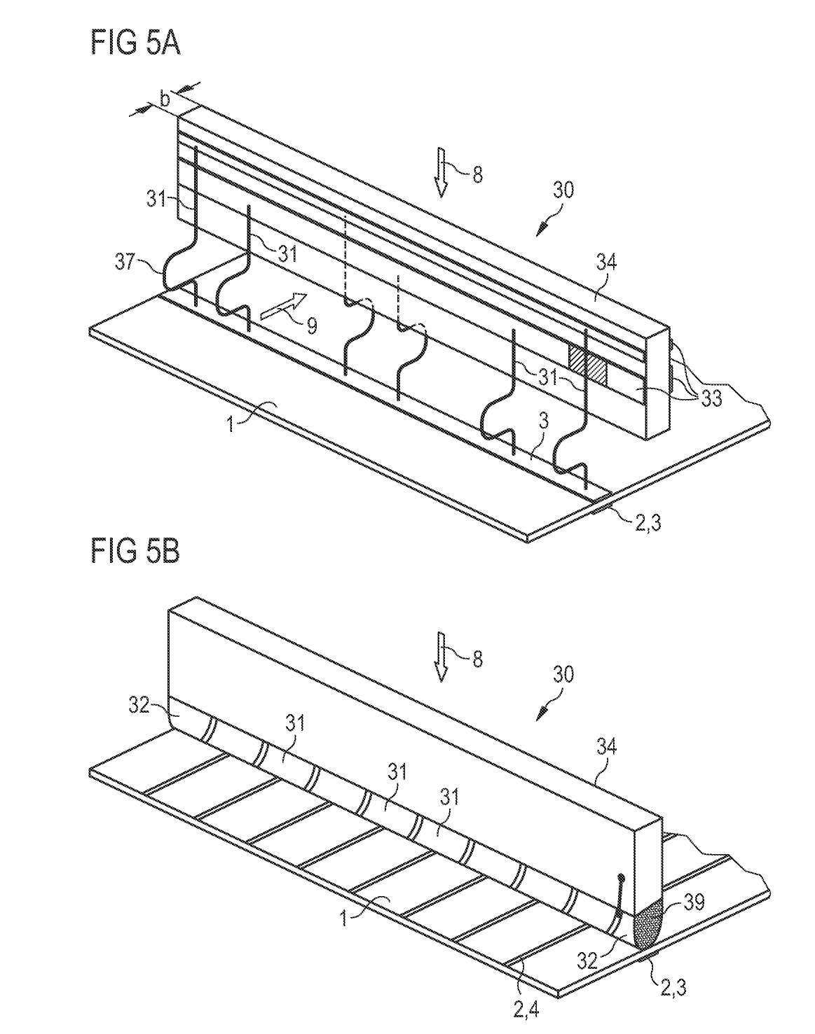

FIGS. 5A, 5B depict various embodiments of probes.

With the method, described below, and the device, which is used to carry out the method, an electrical contact can be formed to a variety of solar cell designs or to solar cells in different fabrication stages, to the extent that the position and size of the electrode terminals of the solar cells make it possible to form a contact to them with the described methods and with the conceivable designs of the probes.

The test rig in FIG. 1 comprises a probe holder 11 on a base plate 10. In this case the probe holder 11 is supposed to be moved in parallel to the base plate 10 with three degrees of freedom. The cross section of the probe holder 11 has the shape of a U, and the probe holder is arranged on the base plate 10 in such a manner that the open side of the U points to the side. Starting from this open side, a plate-shaped sample holder 40 projects into the probe holder 11. The sample holder 40 runs approximately parallel to the base plate 10 and, thus, to the upper and lower leg of the probe holder 11. A solar cell 1 rests and is held on a flat mounting surface 41 of the sample holder 40.

In the embodiment the solar cell is a polycrystalline solar cell, which exhibits on its upwards pointing front side 5 a plurality of current collecting fingers (not illustrated), which are connected together by two bus bars. On its rear side 6 the solar cell exhibits two additional bus bars, which serve together with the front sided bus bars as the electrode terminals 2. In other embodiments a contact can be formed to the fingers as the electrode terminals, in that a common contact element 31 is laid over all of the fingers or in that contact to each finger is formed by a separate contact element 31. The method, described below, allows in conjunction with the probe and the device for carrying out the method a positioning accuracy of up to 50 μm, so that it is also possible to form a contact to the contact pads and their spacing from each other in such orders of magnitude individually by individual contact elements.

Above and below the sample holder 40 there is a probe carrier 20, which is mounted to the probe holder 11 in such a manner that the probe holder plates 20 extend almost parallel to the solar cell 1. Each probe carrier 20 carries two probes 30 with one row of contact elements 31 in each case. These contact elements are placed next to one another on one of the electrode terminals 31, which extend over the entire solar cell 1 perpendicularly to the drawing plane, so that these contact elements are distributed over the length of said electrode terminal for the purpose of forming a contact to the solar cell 1.

Each probe consists of a rail 34, the cross section of which exhibits a trapezoidal shape, of which the shorter of the two parallel base faces points in the direction of the solar cell 1. Each of the two slanted side faces of the trapezoid exhibits a row of contact elements 31, so that they converge to form a tip. The trapezoidal shape of the rail 34 is formed in such a manner that the shadow cast by the probe 30 perpendicularly on the solar cell 1 does not project laterally beyond the area of the respective electrode terminal 3. Moreover, the tips of the contact elements 31 pass over into two rows that lie close to each other in such a manner that the opposite contact elements 31 do not intersect each other. As an alternative, the rail 34 can also exhibit a different shape—for example, with a rectangular cross section—insofar as, on the one hand, it produces together with the contact elements 31 no shadow or just minimal shading on the light active surface of the solar cell 1, and, on the other hand, facilitates a stable and repeatable mounting of the contact elements 31 and optionally also of the reference sensor 31 and/or its reference element 31, and itself exhibits adequate stability, especially with respect to the loads in the direction of the feed motion 8.

The two ends of each probe exhibit a reference element 32 (not illustrated). When the probe 30 is placed with all of its surface over the whole longitudinal expansion of said reference element, a reference signal is generated over the electrode terminal 3, as a result of the high resistive connection between both reference elements 32. In this embodiment this reference signal indicates that the reference element 32 and simultaneously the contact elements 31 are resting on the electrode terminal 3. As an alternative, separate reference sensors 31 can also be arranged on the ends of the probes 30 or at a different location of the probes 30, the probe carriers 20 or the probe holder 11.

The mounting surface 41 of the sample holder 40 exhibits recesses 42, which are adapted to the solar cell 1, to which a contact is to be formed. These recesses are distributed in such a manner that even the undersided electrode terminals 2 of the solar cell 1 remain free so that the probes 30 can extend through the recesses 42 and come to rest on the electrode terminals 2. For this purpose the recesses 42 are adapted in their position and design to the undersided electrode terminals 2 and are elongated slots, which are larger than the electrode terminals 31.

To the extent that in an additional embodiment the electrode terminals are, for example, point shaped, it suffices for the sample holder or its border region to exhibit distributed discrete apertures, as shown in FIG. 2. In this case the electrical contact can be formed by three membered probes 30, comprising a contact element 31 and two reference elements 32—reference sensor. The three elements 31, 32 are arranged so as to be in the immediate vicinity of each other, but electrically insulated from one another. The vicinal arrangement of all three elements 31, 32 permits them to be placed simultaneously on a contact pad as the electrode terminal 2. Such a probe 30 with three elements 31, 32 is used in FIG. 4. The centrally arranged contact element 31 serves to pick off the test signal from the solar cell 1, whereas the two outer elements 32 serve as the reference sensor 32. The electrical connection 33 takes place over a plug connector.

FIG. 4 shows the bilateral contact formation to a solar cell 1 by means of two identical probes 30. Each of the probes 30 is mounted with screws 22 with additional probes (not illustrated in detail) on a probe card 20, also called “probe card.” The probe carrier 20 is larger than the solar cell 1 to be tested and exhibits an aperture 21 in its entire central region that lies over the solar cell 1. Through this aperture 21 extend the contact elements 31 and the reference elements 32 (in this case located one after the other perpendicularly to the drawing plane) in the direction of the solar cell 1, so that they form an acute angle with the surface of the solar cell 1.

The contact elements 31 and the reference elements 32 of each probe 30 rest on an electrode terminal 2. As a result of the feed motions 8 of the probes 30 in the direction of the solar cell 1, which is continued, as described above, for yet another brief period after the first contact, the elements 31, 32 are deflected, as a consequence of the acute angle, in parallel to the surface of the solar cell 1 and then upon completion of the feed motion 9 lie with a certain stress on the electrode terminal 2. The direction of the deflection 9 is shown by the arrows. In consideration of the deflection 8 and the possible geometric tolerances, the feed motion 9 is stopped at such a time that at least the contact elements 31 of all of the probes that are delivered at the same time still lie with certainty on the electrode terminal 2.

Additional embodiments of the probes 30 for forming an electrical contact to electrode terminals 2, which extend in the form of a strip, are shown in FIGS. 5A and 5B. The contact elements 31 in FIG. 5A are arranged side by side in the manner of a comb at a rail 34. For the sake of a better overview, only the individual contact elements 31 are shown. The contact elements 31 consist of molded, elastically flexible electric conductors. The shape of the contact elements 31 exhibiting a protuberance 37 in their central region facilitates their deformation, if following the perpendicular placement on the electrode terminal 2 this feed motion is continued for a short period of time. As explained in detail above, this strategy guarantees that all of the contact elements 31 will rest on the electrode terminal 2.

Owing to the shape of the protuberance 37 and as a result of the feed motion 8 (depicted by a directional arrow), which is carried out perpendicularly to the surface of the solar cell 1, the contact elements 31 experience simultaneously after their touchdown upon continuation of the feed motion 8 such a deflection 9 that runs almost parallel to the surface of the solar cell 1. As a result of this deflection 9, the tips of the contact elements 31 scratch a short distance over the electrode terminal 2, thus scrubbing off (as described above in detail as the “scrub” action) its top layer, usually a passivation layer, and producing a good electrical contact. In order to compensate for a moment acting on the rail owing to the deflection 9 of the contact elements 31, the contact elements 31 are arranged so as to be uniformly distributed over both sides of the rail.

The shape of the contact elements 31 as thin conductors, the width b of the rail and its length guarantee that when the solar cell 1 is illuminated from the top by the probe 30, the result is merely such a shading that does not go beyond or exceeds just slightly the dimension of the electrode terminal 31.

In order to control the feed motion 8, this embodiment uses an optical sensor—for example, a laser triangulation sensor (not illustrated)—which can be mounted on the probe carrier 20 (not illustrated). The reference sensor 32 generates a reference signal, when the reference sensor 32 is located so far above the solar cell 1 that the contact elements 31 just touch the electrode terminal 2.

In the embodiment, according to FIG. 5A, the electrical connection 33 is produced by means of two conductor paths on each side of the rail 34, said paths running along the rail 34. The contact elements 31 are connected electrically and mechanically to the conductor paths by means of soldering joints, but can also be connected in other ways, for example, by clamping or plugging.

Another embodiment of the probe 30 for the purpose of forming an elongated contact, for example, to a bus bar 3 or a row of parallel fingers 4 is shown in FIG. 5B. In this case the contact elements 31 and similarly the two reference elements 32, which are arranged on the edge of the probe, are formed by means of an elastically deformed lip 39 made of a synthetic plastic material. The surface of this lip is electrically conductive in certain sections owing to a coating. Each section represents an element 31, 32. Owing to the arrangement of the reference elements 32 on both ends of the probe 30, it is possible to avoid forming a contact to just one side of this elongated probe 30 as a consequence of its tilting over the longitudinal expansion, because the contact signal is generated only if both ends are resting on the bus bar 3. Owing to the suitable flexible holder of the probe 30 or, as an alternative, owing to the two separate drives (not illustrated), one each for one end of the probe 30, it is possible to avoid a unilateral mechanical load on the solar cell 1 caused by a tilting of the probe 30.

The electrical connection (not illustrated) takes place over the contact conductors and the reference conductors along the rail 34, on whose lower edge the lip 39 is arranged. As an alternative to the conductive surface, the synthetic plastic material itself can also be conductive—for example, due to electrically conductive particles. In this case it is possible to achieve a division of the lip 39 into individual elements 31, 32 by a repeating interruption of the lip 39 itself or its electrical conductivity. A contact to the electrode terminal 2 of the solar cell 1 is formed by pressing down on the lip 39 in a two-dimensional manner over its entire length.

Furthermore, the two probes 30 in FIGS. 5A and 5B can be used to form a bilateral contact to a solar cell 1. In this case the sample holder exhibits elongated recesses. In addition, these probes 30 can be mounted on the probe carriers 20 through suitable adaptations, in order to mount side by side a plurality of probes and to form a contact.

In order to anchor the solar cell on the mounting surface 41 of the sample holder, the sample holder 40 exhibits a plurality of vacuum suction mechanisms 43 (FIG. 2). The number and position of the vacuum suction mechanisms 43 can be adapted to the design and size as well as to the position of the electrode terminals 2 of the solar cell 1 or to additional parameters of the preceding or subsequent handling of the solar cell 1. In the embodiment four vacuum suction mechanisms 43 are selected.

A vacuum suction mechanism 43 is shown in the top view and in the sectional view of FIGS. 3A and 3B. A plate, called the vacuum suction plate, with a plurality of vacuum suction mechanisms 43 is described in detail in DE 198 59 048 A1, to which explicit reference is hereby made. The names of the components of the vacuum suction plate in DE 198 59 048 A1 correspond to the names that are used here.

Each suction hole 45 of a vacuum suction mechanism is connected to the vacuum connection 44, in order to anchor a solar cell 1 that is laid on. As a result of the suction, the seal 46 of each vacuum suction mechanism is totally compressed, so that the solar cell 1 lies with all of its surface on the mounting surface 41 of the sample holder 40. The total surface mounting prevents stresses inside the solar cell 1, if it exhibits irregularities and, thus prevents a fracture during the testing procedure. If the solar cell 1 is anchored on a sample holder 40, in order to handle it in this manner in a sequence of processes for the next fabrication or test steps, the mechanical load and, thus, the loss due to a fracture can be significantly reduced.

In one embodiment one vacuum suction mechanism 43 or a plurality of vacuum suction mechanisms 43 is/are connected separately from the others to the vacuum connection 44, in order to be flexible with respect to the size and number of the solar cells 1 to be held on the sample holder 40.

In order to test a solar cell 1, a temporary contact—that is, only over the defined period of time of the test and detachably—to this solar cell is formed by the probes. This solar cell is exposed to a photoflash, which is aimed at the front side 5 and strikes this front side with almost total coverage. A current and a voltage, which are generated by the effect of the light, are picked off as the measurement signal by the probes, and this signal is passed on to an evaluating unit. The contact is formed only by placing the probes 30 on the electrode terminals 2 of the solar cell 1, the contact is broken by lifting the probes 30 off. In this way it is possible to form continuously in succession a temporary contact to a series of solar cells 1, to test them and to transport them away.

The temporary electrical contact shall be described below by means of the test rig in FIG. 1. First of all, a solar cell 1 is placed on the mounting surface 41 of a sample holder 40 and is anchored on the surface by means of the vacuum suction mechanisms 43. Then the sample holder 40 with the solar cell 1 is positioned inside a probe holder 11 between the opposing probes 30 by means of a positioning device, which is not illustrated.

The probes 30 are aligned beforehand in relation to each other by means of the above-described probe carriers 20 in such a manner that the position of the contact elements 31 to each other matches the arrangement of the electrode terminals 2 on the solar cell 1 to each other. This occurred both for the upper probes 30, which are disposed above the solar cell 1, and for the bottom probes. Moreover, the upper probes with respect to the lower probes are aligned to each other as a function of the position of the upper sided electrode terminals 2 of the solar cell in relation to the bottom sided electrode terminals. Similarly when positioning the solar cell 1, the vertical positions of the individual probes 30 are adjusted exactly to the vertical positions of the electrode terminals 2. The vertical position is defined by the thickness of the sample holder 40 and the solar cell 1, plus the distance of the feed motion 8. After the vertical alignment, the probes 30 exhibit a uniform spacing between each other that corresponds to this measuring chain.

In order to align the probes 30, the probe holder can have means for fine adjustments of the probes 30. The exact alignment of the probes 30 to each other in accordance with the solar cell 1 to be tested and its arrangement on the sample holder 40 makes it possible later to form a contact by means of a single feed motion 8 in only one direction, according to the illustrated coordinate system in FIG. 1, in the Z direction. For the feed motion in the Z direction there are in the embodiment for each probe carrier 20 four guide elements 13. They prevent the probes 30 from tilting out of their planes that run parallel to the X-Y plane. This approach allows for the feed motion 8 of each probe carrier 20 with only one drive and the arrangement of the above-described reference elements 32 on each end of a probe 30. As a result of the above-described distance between the probes 30, the sample holder 40 can be positioned between the probes 30 without changing their relative position.

The sample holder 40 with the solar cell 1 is positioned in the X-Y plane, according to the illustrated coordinate system, and, thus, in the X direction, in the Y direction and at the angle Θ. After the movement of the sample holder 40 into the probe holder 11 and a possible coarse adjustment, the fine adjustment is made by a positioning device 14. In the embodiment said positioning device is combined with the probe holder 11, but can, as an alternative, be assigned just as well to the sample holder 40 and finely adjust said sample holder. In the embodiment the fine adjustment in the X-Y plane between the probe holder 11 and the sample holder 40 is carried out by means of a mounting of the probe holder 11 on three balls between the base plate 10 and the probe holder 11 as well as by means of three suitable drives (not illustrated), acting in this plane.

If the solar cell 1 is positioned exactly between the probes 30, then the feed motion 8 of the upper probes 30 occurs from the top to the bottom jointly via the feed of the upper probe carriers 20 in the feed direction, and the feed motion of the bottom probes 30 occurs from the bottom to the top in the opposite feed direction jointly via the bottom probe carriers 20. Upon reaching the electrode terminals 2 of the solar cell by means of the reference elements 32 at each end of a probe, the reference signals are generated, as described above, in the reference elements 32. These signals are delivered over the electrical connection of the reference elements 32 to a control unit, which stops the feed motion 8 with a pre-determined time delay. In this case the time delay serves only the overtravel since the contact and reference elements 31, 32 touch down at the same time, so that the time delay is determined by trial and error, as described in detail above, from the allowable deflection 9 of the contact elements 31 at a distance travelled in the direction of the feed motion 8 as well as the additional system parameters. Following the illumination of the solar cell 1, the contact is released by a motion of the probes 30 in the direction opposite the feed motion 8.

The described device also supports the testing in a continuous flow process, in that in one embodiment of the method a solar cell 1 is arranged in a first step on a sample holder 40. Thereafter both are positioned together in the probe holder, a contact is formed, and the solar cell 1 is tested. In the interim, in the preceding station the next solar cell 1 is already arranged on an additional sample holder. For positioning the solar cell 1, held by a sample holder 40, in relation to the probe holder and, thus, to the probe, an image of the arrangement of the electrode terminals 2 is taken, and the positioning is performed by evaluating this snapshot. This positioning can be carried out, for example, by a first coarse positioning of the sample holder 40 in the station of the probe holder 11 and then a subsequent fine alignment of the probe holder 11 in the X and Y direction as well as at the angle Θ, according to the coordinate system in FIG. 1. Starting from this position, the electrical contact can be formed by the feed motion 8 in just the Z direction alone.

### LIST OF REFERENCE NUMERALS

1 solar cell

2 electrode terminal

3 bus bar

4 finger

5 front side

6 rear side

8 feed motion

9 deflection

10 base plate

11 probe holder

13 guide elements

14 positioning device

20 probe carrier

21 aperture

22 screw

30 probe

31 contact element

32 reference sensor, reference element

33 electrical connection

34 rail

35 contact conductor

36 reference conductor

37 protuberance

39 lip

40 sample holder

41 mounting surface

42 recess

43 vacuum suction mechanism

44 vacuum connection

45 suction hole

46 seal

47 module

48 receiving opening

49 ring groove

50 support ring

51 screw

52 borehole

53 arch

1. A method for forming a temporary electrical contact to a solar cell for testing purposes,
holding at least one solar cell by a sample holder, said solar cell comprising at least two electrode terminals, on which the electrical contact is formed,
holding at least one probe, which serves to form a contact to an electrode terminal, by a probe holder, the probe being moveable in at least one direction and comprising at least one elastic, electrically conductive contact element and at least one reference sensor, in order to indicate a distance of the contact element from an electrode terminal,
positioning the solar cell or the probe relative to each other in such a manner that the electrode terminal of the solar cell and the probe are opposite each other so as to be spaced apart in a possible movement direction of the probe,
carrying out a feed motion of the probe to an electrode terminal in said movement direction until the reference sensor of the probe generates, upon reaching a pre-defined, known distance of the reference sensor from a reference surface on the solar cell, an electric reference signal, and
continuing the feed motion by a predefined path that goes beyond the contact element touching the electrode terminal, in order to carry out an overtravel of the contact element.

2. Method, as claimed in claim 1, wherein the feed motion of the probe, exhibiting a torsion spring as the contact element, is carried out, wherein after generating the reference signal, the contact element of the probe experiences a deflection movement out of a resting position during overtravel in such a manner that the deflection movement exhibits a directional component in the movement direction of the feed motion and a directional component at right angles thereto.

3. Method, as claimed in claim 1, wherein an electrode terminal on a front side and an electrode terminal on a rear side of the solar cell form an electrical contact to one probe respectively.

4. Method, as claimed in claim 3, wherein a solar cell is positioned between at least one pair of two opposite probes, and both probes form a contact to the solar cell by opposite feed motions.

5. Method, as claimed in claim 1, wherein a rear side of the solar cell rests on the sample holder, and an electrode terminal on the rear side of the solar cell forms a contact by way of an electric conductor of the sample holder.

6. Method, as claimed in claim 1, wherein an electrode terminal of a solar cell forms a simultaneous contact by several contact elements of a probe.

7. Method, as claimed in claim 1, wherein at least two electrode terminals on a same side of a solar cell form a simultaneous contact by at least two probes.

8. Method, as claimed in claim 6, wherein the feed motion of a probe for forming a linear or a two-dimensionally expanded contact to an electrode terminal or a probe arrangement, which comprises a plurality of probes, which are distributed linearly or two-dimensionally, is controlled by at least two reference sensors, which are spaced apart from each other and which both generate a separate reference signal, and wherein the feed motion of the probe or the probe arrangement is made up of two partial movements, which are controlled independently of each other by the two reference sensors.

9. Method, as claimed in claim 1, wherein the reference signal is generated as a result of the reference sensor coming into contact with the reference surface on the solar cell.

10. Method, as claimed in claim 1, wherein the reference surface is an electrode terminal of the solar cell.

11. Method, as claimed in claim 1, wherein the solar cell is arranged in a first step on the sample holder, and then subsequently the solar cell, connected to the sample holder, and a probe are positioned relative to each other.

12. Method, as claimed in claim 1, wherein the solar cell and the probe are positioned in relation to each other by a snapshot and an image evaluation of the electrode terminal on the solar cell.

13. A probe for forming a temporary electrical contact to a solar cell for testing purposes, comprising:
at least one elastic, electrically conductive contact element, having a tip, for forming the electrical contact,
at least one reference sensor for indicating a distance of the contact element from a reference surface, and
one mounting plane, with respect to which the tip of the contact element is aligned.

14. Probe, as claimed in claim 13, wherein a plurality of contact elements are arranged side by side in such a manner that tips of the elements lie in a plane, wherein the contact elements are connected in parallel and wherein at least two reference sensors are arranged so as to be spaced apart from each other.

15. Probe, as claimed in claim 13, wherein the at least one contact elements comprises an electrically conductive torsion spring.

16. Probe, as claimed in claim 13, wherein the at least one contact element comprises an elastically deformable, electrically conductive plastic body.

17. Probe, as claimed in claim 13, wherein the reference sensor comprises two elastically, electrically conductive reference elements, which are arranged so as to be electrically insulated in relation to the contact element and adjacent to said at least one contact element in such a manner that the reference elements and the at least one contact element can be placed side by side on an electrode terminal of the solar cell.

18. A device for forming a temporary electrical contact to a solar cell for testing purposes, comprising:
a sample holder with a mounting surface for receiving a solar cell, having at least one electrode terminal,
a probe holder, which holds at least one probe, as claimed in claim 13, and comprises a motion device, for carrying out a feed motion of the at least one probe to the solar cell,
a positioning device for positioning the solar cell or the at least one probe relative to one another, and
a control unit for controlling the feed motion of the at least one probe, the central unit being electrically connected to each reference sensor of the probe.

19. Device, as claimed in claim 18, wherein a plurality of probes are arranged on a probe carrier and are held by the probe holder by way of said probe carrier.

20. Device, as claimed in claim 18, wherein the probe holder comprises at least two reference sensors, and the at least one probe is held in a statically determined manner by the probe holder.

21. Device, as claimed in claim 20, wherein the motion device of the probe holder comprises at least two drives with a force attack, which are spaced apart from each other, and the drives are controlled separately based on reference signals of both reference sensors.

22. Device, as claimed in claim 18, wherein at least two probes are arranged on the probe holder in such a manner that the probes lie opposite each other, and the sample holder with the solar cell can be positioned between the probes.

23. Device, as claimed in claim 18, wherein the sample holder comprises at least one vacuum suction mechanism, with a suction hole in the mounting surface, wherein the suction hole adjoins a vacuum source and is surrounded by an inflatable lip, which forms a closed ring in the mounting surface and which in a non-inflated state seals flush with the mounting surface.

24. Device, as claimed in claim 18, wherein the sample holder comprises at least one recess, by which a probe can form a contact to the solar cell on a side of the cell which rests on the sample holder.

25. Device, as claimed in claim 18, further comprising an image capturing unit for taking and evaluating an image of the solar cell, said unit being connected to the positioning device to control the positioning of the solar cell and the at least one probe in relation to each other.
